(19) United States
(12) Patent Application Publication
(10) Pub. No.: US 2024/0387318 A1
(43) Pub. Date: Nov. 21, 2024

(54) SEMICONDUCTOR DEVICE

(71) Applicants: DENSO CORPORATION, Kariya-City (JP); TOYOTA JIDOSHA KABUSHIKI KAISHA, Toyota-shi (JP); MIRISE Technologies Corporation, Nisshin-shi (JP)

(72) Inventors: Ryota KOJIMA, Nisshin-shi (JP); Akihiro YAMAGUCHI, Nisshin-shi (JP)

(21) Appl. No.: 18/631,290

(22) Filed: Apr. 10, 2024

(30) Foreign Application Priority Data
May 15, 2023 (JP) 2023-080195

(51) Int. Cl. H01L 23/367; H01L 23/31; H01L 23/373; H01L 23/473; H01L 25/07; H02M 3/335

(52) U.S. Cl. CPC H01L 23/3677; H01L 23/3142; H01L 23/3731; H01L 23/473; H01L 25/072; H02M 3/33569

(57) ABSTRACT

A semiconductor device includes a wiring board having a wiring pattern, a semiconductor package, and a heat dissipation member. The semiconductor package includes a heat dissipation substrate, a semiconductor chip formed with a semiconductor element and arranged on the heat dissipation substrate, and an element pad electrically connected to the semiconductor chip. The semiconductor package is mounted on the wiring board, and the element pad is connected to the wiring pattern. The heat dissipation member is disposed opposite to the wiring board with respect to the semiconductor package, and is thermally connected to the insulating heat dissipation substrate. The wiring pattern includes a heat dissipation pattern that is connected to the semiconductor element and allows a current according to an operation of the semiconductor element to flow. A heat dissipation connection member is disposed between the heat dissipation pattern and the insulating heat dissipation substrate to thermally connect therebetween.

### CROSS REFERENCE TO RELATED APPLICATION

The present application claims the benefit of priority from Japanese Patent Application No. 2023-080195 filed on May 15, 2023. The entire disclosures of the above application are incorporated herein by reference.

### TECHNICAL FIELD

The present disclosure relates to a semiconductor device in which a semiconductor package is mounted on a wiring board.

### BACKGROUND

It has been known a semiconductor device in which a semiconductor package having a semiconductor chip is mounted on a wiring board. In such a semiconductor device, the wiring board is arranged on one side of the semiconductor package, and a heat dissipation member is arranged on the other side of the semiconductor package. In such a semiconductor device, heat generated from the semiconductor package is dissipated from the heat dissipation member. The wiring board is formed with a predetermined wiring pattern. The wiring pattern is electrically connected to the semiconductor chip included in the semiconductor package. The wiring pattern allows a current to flow therein in accordance with the operation of the semiconductor chip.

### SUMMARY

The present disclosure describes a semiconductor device. In an aspect, a semiconductor device includes a wiring board, a semiconductor package, a heat dissipation member, and a heat dissipation connection member. The wiring board has a wiring pattern. The semiconductor package includes a heat dissipation substrate, a semiconductor chip formed with a semiconductor element and arranged on the heat dissipation substrate, and an element pad electrically connected to the semiconductor chip. The semiconductor package is mounted on the wiring board, and the element pad is connected to the wiring pattern. The heat dissipation member is disposed opposite to the wiring board with respect to the semiconductor package, and is thermally connected to the insulating heat dissipation substrate. The wiring pattern includes a heat dissipation pattern that is connected to the semiconductor element and allows a current to flow therein according to an operation of the semiconductor element. The heat dissipation connection member is disposed between the heat dissipation pattern and the insulating heat dissipation substrate to thermally connect between the heat dissipation pattern and the insulating heat dissipation substrate.

### BRIEF DESCRIPTION OF DRAWINGS

FIG. 1 is a circuit diagram of a power conversion device according to a first embodiment;

FIG. 2 is a cross-sectional view of a semiconductor device according to the first embodiment;

FIG. 3 is a cross-sectional view of a semiconductor package of the semiconductor device shown in FIG. 1;

FIG. 4 is a plan view of the semiconductor package;

FIG. 5 is a plan view of a second surface side of a wiring board;

FIG. 6 is a diagram showing heat dissipation paths in the semiconductor device according to the first embodiment;

FIG. 7 is a cross-sectional view of a semiconductor device according to a second embodiment;

FIG. 8 is a diagram showing heat dissipation paths in the semiconductor device according to the second embodiment;

FIG. 9 is a cross-sectional view of a semiconductor device according to a third embodiment;

FIG. 10 is a cross-sectional view of a semiconductor device according to a fourth embodiment; and

FIG. 11 is a cross-sectional view of a semiconductor device according to a fifth embodiment.

### DETAILED DESCRIPTION

To begin with, a relevant technology will be described only for understanding the embodiments of the present disclosure.

In a semiconductor device in which a semiconductor package having a semiconductor chip is mounted on a wiring board, the wiring board is arranged on one side of the semiconductor package, and a heat dissipation member is arranged on the other side of the semiconductor package. In such a semiconductor device, heat generated from the semiconductor package is dissipated from the heat dissipation member. The wiring board is formed with a predetermined wiring pattern, and the wiring pattern is electrically connected to the semiconductor chip included in the semiconductor package. The wiring pattern allows an electric current to flow therein in accordance with the operation of the semiconductor chip.

When such a semiconductor device is made to be applicable to high output, a large quantity of current flows through the wiring pattern on the wiring board, and the wiring pattern also generates heat. In this case, the heat generated from the wiring pattern on the wiring board is dissipated to the heat dissipation member via the semiconductor package. However, since the semiconductor chip also generates heat, there is a concern that the heat of the wiring board will not be sufficiently dissipated to the heat dissipation member.

The present disclosure provides a semiconductor device that can also easily dissipate heat generated from a wiring board.

According to an aspect of the present disclosure, a semiconductor device includes a wiring board, a semiconductor package and a heat dissipation member. The wiring board has a first surface and a second surface opposite to the first surface, and includes a wiring pattern disposed on the second surface. The semiconductor package includes a semiconductor chip formed with a semiconductor element, an insulating heat dissipation substrate having a first surface on which the semiconductor chip is arranged and a second surface, and an element pad being electrically connected to the semiconductor chip. The semiconductor package is mounted on the wiring board so that the element pad is connected to the wiring pattern. The heat dissipation member is disposed opposite to the wiring board with respect to the semiconductor package. The heat dissipation member faces the second surface of the insulating heat dissipation substrate of the semiconductor package and is thermally connected to the insulating heat dissipation substrate. The wiring pattern includes a heat dissipation pattern that is connected to the semiconductor element and allows a current to flow therein according to an operation of the semiconductor element. The semiconductor device further includes a heat dissipation connection member disposed between the heat dissipation pattern and the insulating heat dissipation substrate. The heat dissipation connection member thermally connects the heat dissipation pattern and the insulating heat dissipation substrate.

In such a configuration, since the heat dissipation pattern is thermally connected to the insulating heat dissipation substrate through the heat dissipation connection member, heat of the heat dissipation pattern can be effectively dissipated to the insulating heat dissipation substrate. Accordingly, the heat can be easily dissipated through the insulating heat dissipation substrate.

Embodiments of the present disclosure will be described hereinafter with reference to the drawings. In the following description, the same or equivalent parts are denoted by the same reference numerals throughout the embodiments.

### First Embodiment

The following describes a first embodiment with reference to the drawings. An example in which a semiconductor device of the present embodiment is used to form a step-down DC-to-DC converter as a power conversion device will be described below. First, a circuit configuration of the power conversion device will be briefly described.

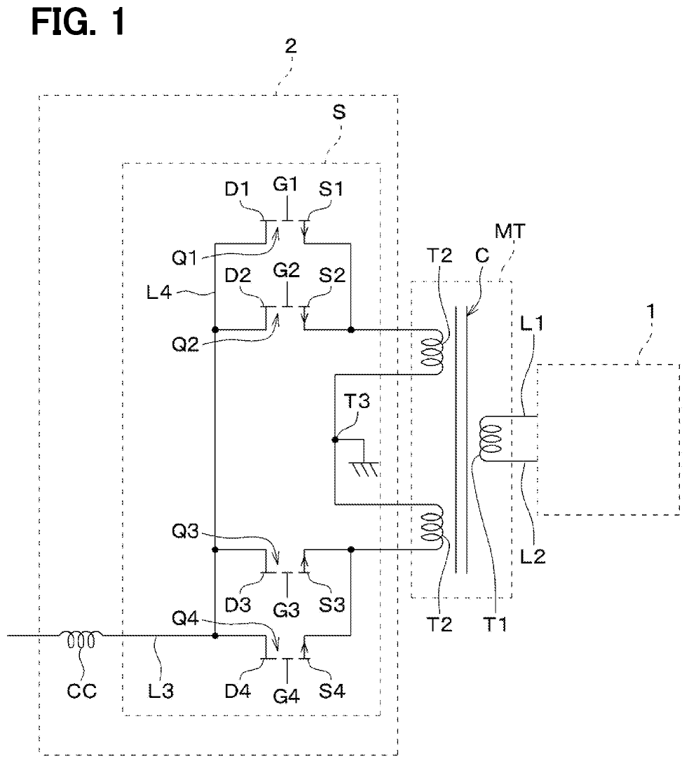

As shown in FIG. 1, the power conversion device has a primary-side component unit 1, a main transformer unit MT, and a secondary-side component unit 2. Although detailed explanation is omitted, the primary-side component unit 1 includes two sets of transistors connected in series. The primary-side component unit 1 also has a first output wiring L1 connected to a portion between two series-connected transistors of one of the two sets, and a second output wiring L2 connected to a portion between two series-connected transistors of the other of the two sets.

The main transformer unit MT includes a primary winding T1, a secondary winding T2, a core C, and the like. The primary winding T1 has one end connected to the first output wiring L1 of the primary-side component unit 1, and the other end connected to the second output wiring L2 of the primary-side component unit 1.

The secondary-side component unit 2 has an intermediate tap T3 arranged at an intermediate position of the secondary winding T2 and connected to ground. Further, the secondary-side component unit 2 includes a first transistor Q1 and a second transistor Q2 that are arranged between one end of the secondary winding T2 and an external output wiring L3 connected to a choke coil CC. The secondary-side component unit 2 includes a third transistor Q3 and a fourth transistor Q4 that are arranged between the other end the secondary winding T2 and the external output wiring L3. Specifically, the first transistor Q1 and the second transistor Q2 are arranged in parallel, so that their respective source electrodes S1 and S2 are connected to the one end of the secondary winding T2, and their respective drain electrodes D1 and D2 are connected to the external output wiring L3. The third transistor Q3 and the fourth transistor Q4 are arranged in parallel, so that their respective source electrodes S3 and S4 are connected to the other end of the secondary winding T2, and their respective drain electrodes D3 and D4 are connected to the external output wiring L3. Further, first to fourth gate electrodes G1 to G4 of the first to fourth transistors Q1 to Q4 are respectively connected to a control circuit (not shown).

The drain electrodes D1 to D4 of the first to fourth transistors Q1 to Q4 are connected to a connection wiring L4, and are thus connected to the external output wiring L3 through the connection wiring L4. In the present embodiment, the drain electrodes D1 to D4 of the first to fourth transistors Q1 to Q4 are arranged in parallel to each other and are aligned in the order of the first to fourth transistors Q1 to Q4 with respect to the connection wiring L4. The external output wiring L3 is connected to the connection wiring L4 at the end of the connection wiring L4 adjacent to the fourth transistor Q4.

In the present embodiment, the power conversion device has the circuit configuration as described above. In such a power conversion device, a current flows through the secondary winding T2 in accordance with the current flowing through the primary winding T1, and the current also flows through the first to fourth transistors Q1 to Q4. In this case, a large quantity of current, which is the sum of the currents flowing through the first to fourth transistors Q1 to Q4, flows through the external output wiring L3. As such, the external output wiring L3 easily generates heat. To the connection wiring L4, the first to fourth transistors Q1 to Q4 are arranged in parallel to each other. Further, the external output wiring L3 is connected to the end of the connection wiring L4 on the side adjacent to the fourth transistor Q4. Therefore, the quantity of current increases toward the fourth transistor Q4. In the connection wiring L4, the quantity of current is larger in a portion adjacent to the fourth transistor Q4, and thus the amount of heat generation is higher in the portion adjacent to the fourth transistor Q4.

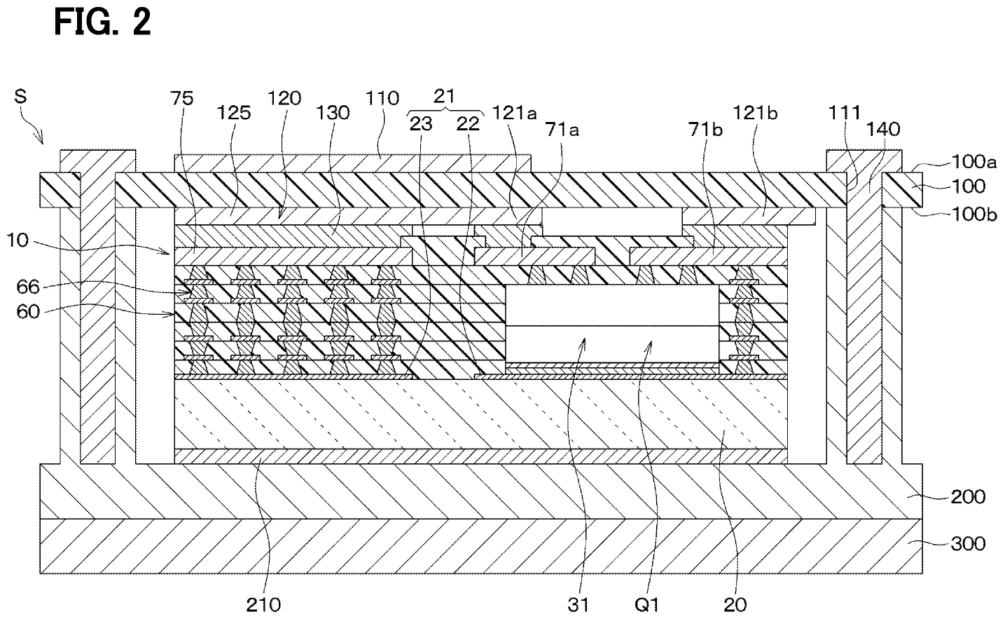

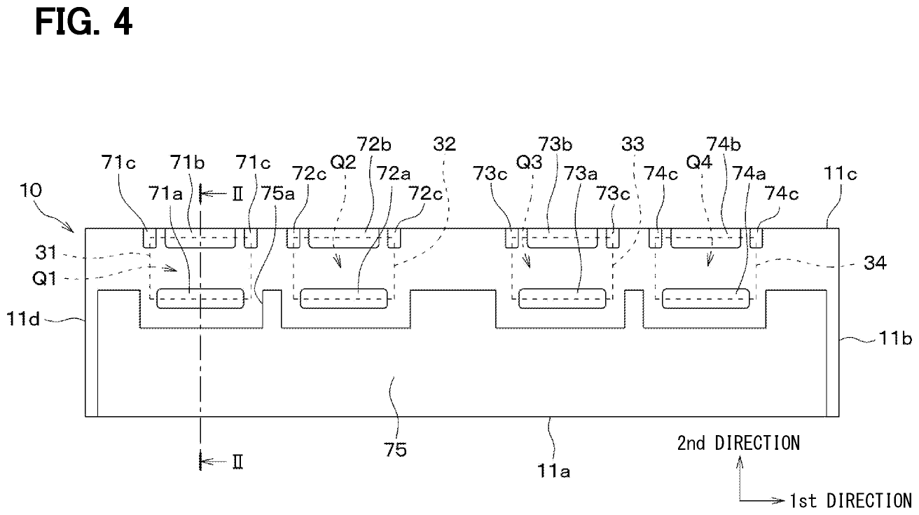

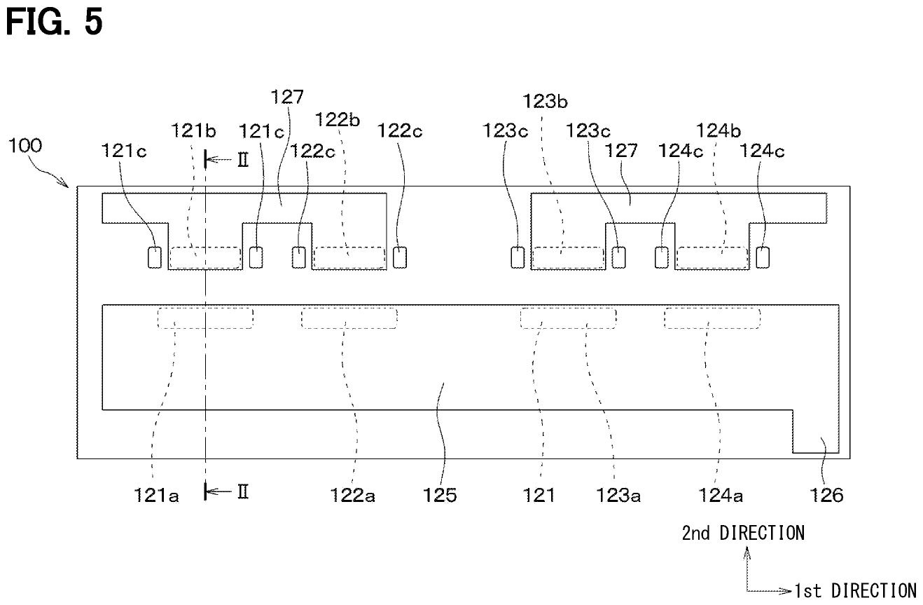

Next, the configuration of a semiconductor device S constituting the power conversion device described above will be described with reference to FIGS. 2 to 5. The view including a semiconductor package 10 and a wiring board 100 shown in FIG. 2 corresponds to a cross-sectional view taken along a line II-II in FIG. 4 and FIG. 5. The semiconductor device S of the present embodiment is configured so as to include the first to fourth transistors Q1 to Q4, the external output wiring L3, the connection wiring 4 and the like of the power conversion device described above, as also shown in FIG. 1. The power conversion device described above is configured by combining the semiconductor device S of the present embodiment with, for example, the primary-side component unit 1 and the main transformer unit MT, which are configured separately from the semiconductor device S.

As shown in FIG. 2, the semiconductor device S includes the semiconductor package 10, the wiring board 100, a heat dissipation member 200, and the like.

As shown in FIGS. 2 to 4, the semiconductor package 10 includes an insulating heat dissipation substrate 20, first to fourth semiconductor chips 31 to 34, a sealing member 60, and the like. Note that the second to fourth semiconductor chips 32 to 34 appear in cross-sections different from the cross-section shown in FIG. 2.

The insulating heat dissipation substrate 20 is made of silicon nitride (SiN), aluminum nitride (AlN), or the like. The insulating heat dissipation substrate 20 has a plate shape having a first surface 20a and a second surface 20b opposite to the first surface 20a. The insulating heat dissipation substrate 20 is formed with a wiring layer 21 made of copper or the like on the first surface 20a. The wiring layer 21 of the present embodiment includes a chip wiring layer 22 and a heat dissipation wiring layer 23. In the present embodiment, the chip wiring layer 22 and the heat dissipation wiring layer 23 are provided separately. Further, the wiring layer 21 includes four chip wiring layers 22, and the four chip wiring layers 22 are separated from each other.

The first to fourth semiconductor chips 31 to 34 have the same basic configuration. Therefore, the first semiconductor chip 31 will be described below as an example.

In the present embodiment, the first semiconductor chip 31 is configured by using a semiconductor substrate 43 in which a semiconductor layer 42 containing gallium nitride is stacked on a silicon substrate 41 made of silicon. In other words, the first semiconductor chip 31 is configured by using the semiconductor substrate 43 that is so-called GaN-on-Si. The first semiconductor chip 31 has a front surface 31a provided by the semiconductor layer 42 and a rear surface 31b provided by the silicon substrate 41.

The semiconductor layer 42 containing gallium nitride of the present embodiment is configured by stacking epitaxial layers such as a gallium nitride (GaN) layer and an aluminum gallium nitride (AlGaN) layer. In the present embodiment, a two-dimensional electron gas (i.e., two DEG) is formed at the interface between the gallium nitride layer and the aluminum gallium nitride layer.

Although not particularly shown in the drawings, the first semiconductor chip 31 has the drain electrode D1, the source electrode S1, and the gate electrode G1 on the front surface 31a side. In the first semiconductor chip 31 of the present embodiment, as the first transistor Q1, a high electron mobility transistor that causes a current to flow between the drain electrode D1 and the source electrode S1 utilizing the two-dimensional electron gas is formed. That is, the semiconductor chip 31 is formed with a horizontal transistor as the first transistor Q1 in which the current flows in a planar direction of the semiconductor substrate 43.

Further, the first semiconductor chip 31 is formed with a rear surface electrode 44 on the rear surface 31b side. The rear surface electrode 44 is electrically connected to the source electrode S1 of the first transistor Q1, as will be described later in detail. As a result, the first semiconductor chip 31 of the present embodiment is designed to suppress current collapse.

Note that, as described above, the configurations of the first to fourth semiconductor chips 31 to 34 are the same. The second transistor Q2 is formed in the second semiconductor chip 32, the third transistor Q3 is formed in the third semiconductor chip 33, and the fourth transistor Q4 is formed in the fourth semiconductor chip 34. In the present embodiment, the first to fourth transistors Q1 to Q4 correspond to semiconductor elements.

The first to fourth semiconductor chips 31 to 34 of the present embodiment have the configurations as described above. The first semiconductor chip 31 is placed on one of the chip wiring layers 22 formed on the insulating heat dissipation substrate 20 via a bonding member 50, with the rear surface electrode 44 facing the insulating heat dissipation substrate 20. In the present embodiment, the bonding member 50 is provided by a conductive member such as a sintered body containing silver tin (AgSn) as a main component. Therefore, the rear surface electrode 44 is electrically connected to the chip wiring layer 22 through the bonding member 50. Note that the chip wiring layer 22 is formed to protrude beyond the first semiconductor chip 31 when viewed along the direction normal to the first surface 20a of the insulating heat dissipation substrate 20. Hereinafter, the direction normal to the first surface 20a will be simply referred to as the normal direction.

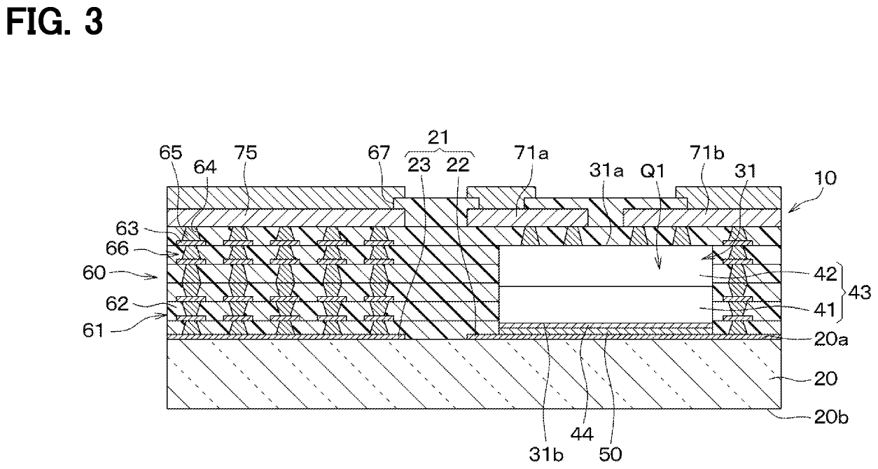

In a cross section different from the cross section shown in FIG. 3, each of the second to fourth semiconductor chips 32 to 34 is placed on the corresponding chip wiring layer 22 formed on the insulating heat dissipation substrate 20 through the bonding member 50 with the rear surface electrode 44 thereof facing the insulating heat dissipation substrate 20, similarly to the first semiconductor chip 31.

The sealing member 60 is arranged on the insulating heat dissipation substrate 20 so as to be bonded to the insulating heat dissipation substrate 20 while sealing the first to fourth semiconductor chips 31 to 34. However, the sealing member 60 is arranged on the insulating heat dissipation substrate 20 so as to expose the second surface 20b of the insulating heat dissipation substrate 20. The sealing member 60 of the present embodiment is composed of a multilayer sealing member including a plurality of plate members 61 stacked and integrated.

Specifically, the plate members 61 have film portions 62 made of liquid crystal polymer, epoxy resin, or the like, patterns 63 formed in the film portions 62, and connection vias 65 arranged in through holes 64 formed in the film portions 62. The connection vias 65 are formed by sintering a conductive paste.

As shown in FIGS. 3 and 4, a first drain pad 71a, a first source pad 71b, and a first gate pad 71c are formed, as the patterns 63, in the plate member 61 located above the first semiconductor chip 31. Similarly, as shown in FIG. 4, a second drain pad 72a, a second source pad 72b, and a second gate pad 72c are formed in the plate member 61 located above the second semiconductor chip 32. A third drain pad 73a, a third source pad 73b, and a third gate pad 73c are formed in the plate member 61 located above the third semiconductor chip 33. A fourth drain pad 74a, a fourth source pad 74b, and a fourth gate pad 74c are formed in the plate member 61 located above the fourth semiconductor chip 34. In the present embodiment, the first to fourth drain pads 71a to 74a, the first to fourth source pads 71b to 74b, and the first to fourth gate pads 71c to 74c correspond to element pads.

The pads 71a to 74c are formed on the same plate member 61. Furthermore, a heat dissipation pad 75 is formed on the plate member 61 on which the respective pads 71a to 74c are formed. As shown in FIG. 3, of the plate members 61, the plate member 61 located on a side opposite to the insulating heat dissipation substrate 20 is formed with contact holes 67 to expose the pads 71a to 75.

In the present embodiment, as shown in FIG. 4, the semiconductor package 10 has a substantially rectangular shape as a planar shape, which has first to fourth sides 11a to 11d forming two pairs, when viewed along the normal direction. The first side 11a and the third side 11c are long sides of the rectangular shape. Hereinafter, the direction along the first and third sides 11a and 11c will be referred to as a first direction, and the direction along the second and fourth sides 11b and 11d will be referred to as a second direction.

The heat dissipation pad 75 is arranged adjacent to the first side 11a and along the first direction. In the present embodiment, the heat dissipation pad 75 has recesses 75a on the side adjacent to the third side 11c. The heat dissipation pad 75 has four recesses 75a along the first direction.

The first to fourth drain pads 71a to 74a are respectively arranged in the recesses 75a formed in the heat dissipation pad 75 in the order of the first to fourth drain pads 71a to 74a along the first direction. The first to fourth source pads 71b to 74b are provided next to the first to fourth drain pads 71a to 74a, respectively, in the second direction.

Note that the intervals between the first to fourth drain pads 71a to 74a are adjusted as appropriate depending on the sizes or the like of the first to fourth semiconductor chips 31 to 34. Further, the respective distances between the first to fourth drain pads 71a to 74a and the first to fourth source pads 71b to 74b are adjusted depending on the respective distances between the drain electrodes D1 to D4 and the source electrodes S1 to S4 formed in the first to fourth semiconductor chips 31 to 34.

Each of the first to fourth gate pads 71c to 74c includes two pad portions, and the two pad portions are arranged so as to interpose the corresponding one of the first to fourth source pads 71b to 74b therebetween.

As shown in FIG. 3, the connection via 65 formed in the plate member 61 connects the first drain pad 71a and the first drain electrode D1 (not shown) formed in the first semiconductor chip 31. The connection via 65 formed in the plate member 61 connects the first source pad 71b and the first source electrode S1 (not shown) formed in the first semiconductor chip 31. The connection via 65 formed in the plate member 61 connects the first gate pad 71c and the first gate electrode G1 formed in the first semiconductor chip 31 in a cross section different from that shown in FIG. 3. The connection via 65 formed in the plate member 61 connects the first source pad 71b and the chip wiring layer 22. In this way, the rear surface electrode 44 and the first source electrode S1 of the first semiconductor chip 31 are electrically connected.

Moreover, the connection via 65 formed in the plate member 61 is formed so as to thermally connect the heat dissipation pad 75 and the heat dissipation wiring layer 23 formed on the insulated heat dissipation substrate 20. Hereinafter, the part connecting the heat dissipation pad 75 and the heat dissipation wiring layer 23 will also be collectively referred to as the heat dissipation via 66. In the present embodiment, the heat dissipation via 66 have a substantially cylindrical shape. The semiconductor package 10 has a plurality of heat dissipation vias 66. In the present embodiment, the heat dissipation via 66 corresponds to a heat dissipation connection member. Furthermore, the heat dissipation via 66 is formed by sintering the conductive paste. Therefore, the heat dissipation pad 75 and the heat dissipation wiring layer 23 are also electrically connected through the heat dissipation via 66.

Although not particularly shown, the second to fourth semiconductor chips 32 to 34, the second to fourth drain pads 72a to 74a, the second to fourth source pads 72b to 74b, and the second to fourth gate pads 72c to 74c are similarly connected through the connection vias 65, respectively. The semiconductor package 10 of the present embodiment have the configurations as described above.

As shown in FIG. 2, the wiring board 100 is provided by a printed circuit board or the like. The wiring board 100 has a first surface 100a and a second surface 100b. The wiring board 100 has a substantially rectangular shape as a planar shape. The wiring board 100 has a first wiring pattern 110 on the first surface 100a side, and a second wiring pattern 120 on the second surface 100b side. Further, although not particularly illustrated, the first wiring pattern 110 and the second wiring pattern 120 are appropriately electrically connected by a through via formed in a thickness direction of the wiring board 100.

As shown in FIG. 5, the second wiring pattern 120 is formed corresponding to each of the pads 71a to 75 of the semiconductor package 10. In the present embodiment, the second wiring pattern 120 includes first to fourth drain patterns 121a to 124a, first to fourth source patterns 121b to 124b, first to fourth gate patterns 121c to 124c, and a heat dissipation pattern 125. The second wiring pattern 120 further includes an external output pattern 126 and a connection pattern 127.

Specifically, the first to fourth drain patterns 121a to 124a are arranged in order along the first direction. The heat dissipation pattern 125 is arranged to connect the first to fourth drain patterns 121a to 124a. Note that the heat dissipation pattern 125 constitutes the connection wiring L4 in FIG. 1 described above.

The external output pattern 126 is connected to one end of the heat dissipation pattern 125 in the first direction. In the present embodiment, the external output pattern 126 is connected to the end of the heat dissipation pattern 125 on the fourth drain pattern 124a side. Note that the external output pattern 126 constitutes the external output wiring L3 in FIG. 1 described above.

The first to fourth source patterns 121b to 124b are arranged next to the first to fourth drain patterns 121a to 124a, respectively, in the second direction. In the present embodiment, since the first transistor Q1 and the second transistor Q2 are arranged in parallel as described above, the first source pattern 121b and the second source pattern 122b are connected to each other through the connection pattern 127. Similarly, since the third transistor Q3 and the fourth transistor Q4 are arranged in parallel as described above, the third source pattern 123b and the fourth source pattern 124b are connected to each other through the connection pattern 127.

Each of the first to fourth gate patterns 121c to 124c includes two pattern portions, and the two pattern portions are arranged to interpose the corresponding one of the first to fourth source patterns 121b to 124b therebetween.

In the semiconductor package 10, as shown in FIG. 2, the first drain pad 71a is connected to the first drain pattern 121a through the bonding member 130. The first source pad 71b is connected to the first source pattern 121b through the bonding member 130. The heat dissipation pad 75 is connected to the heat dissipation pattern 125 through the bonding member 130.

Further, in a cross section of the semiconductor package 10 different from that shown in FIG. 2, the second to fourth drain pads 72a to 74a are connected to the second to fourth drain patterns 122a to 124a through the bonding member 130, respectively. The second to fourth source pads 72b to 74b are connected to the second to fourth source patterns 122b to 124b through the bonding member 130, respectively. The first to fourth gate pads 71c to 74c are connected to the first to fourth gate patterns 121c to 124c through the bonding member 130, respectively.

The heat dissipation member 200 is arranged opposite to the wiring board 100 with respect to the semiconductor package 10. The heat dissipation member 200 fixes the wiring board 100 and the semiconductor package 10. Specifically, the wiring board 100 is fixed to the heat dissipation member 200 by inserting a fastening member 140 made of a screw or the like into insertion holes 111 of the wiring board 100 and fastening the fastening member 140 to the heat dissipation member 200.

More specifically, the wiring board 100 is fixed to the heat dissipation member 200 with the second surface 100b facing the heat dissipation member 200. Further, the wiring board 100 is fixed to the heat dissipation member 200 such that the second surface 20b of the insulating heat dissipation substrate 20 of the semiconductor package 10 is bonded to the heat dissipation member 200 through the bonding member 210. Thus, the heat of the semiconductor package 10 can be efficiently released to the heat dissipation member 200. Note that the bonding member 210 is made of grease or the like having high thermal conductivity, and the heat dissipation member 200 is made of a metal housing or the like having high thermal conductivity.

Furthermore, in the semiconductor device S of the present embodiment, a cooling member 300 is arranged on the side of the heat dissipation member 200 opposite to the semiconductor package 10 so that the heat of the heat dissipation member 200 can be efficiently dissipated. For example, the cooling member 300 is configured by a pipe that allows a cooling water or the like to flow.

The semiconductor device S of the present embodiment has the configurations as described above. In a case where the power conversion device described above is configured using the semiconductor device S described above, the heat dissipation pattern 125 and the external output pattern 126 in the wiring board 100 are likely to generate heat due to the flow of a large quantity of current.

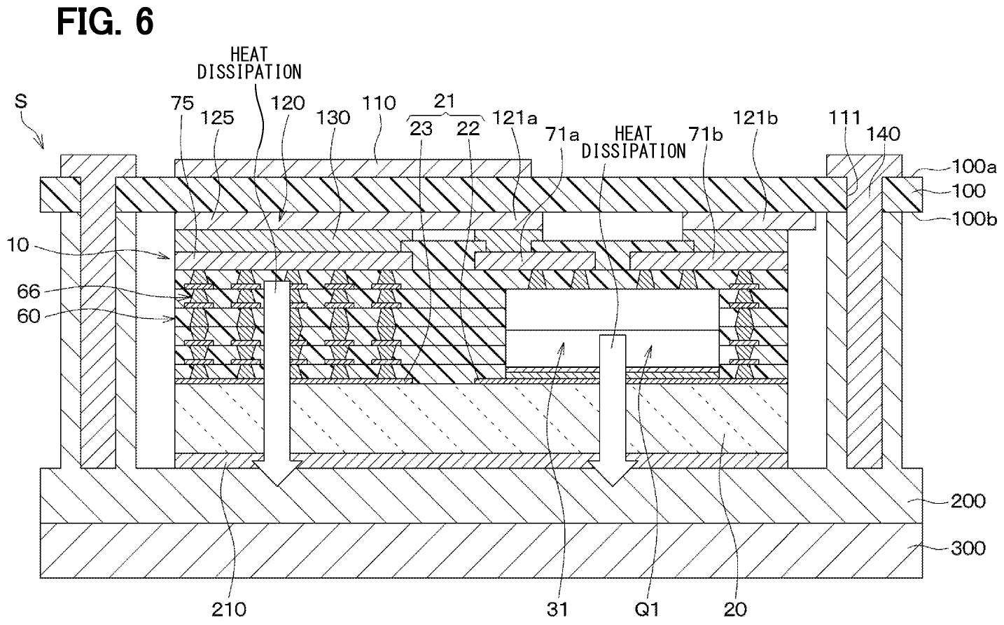

In the present embodiment, the heat dissipation pattern 125 and the external output pattern 126 are thermally connected to the heat dissipation wiring layer 23 (i.e., the insulating heat dissipation substrate 20) through the heat dissipation via 66. Therefore, as shown in FIG. 6, the heat generated from the heat dissipation pattern 125 and the external output pattern 126 can be effectively dissipated from the insulating heat dissipation substrate 20 to the heat dissipation member 200. Note that the heat generated in the semiconductor package 10 is dissipated from the insulating heat dissipation substrate 20 to the heat dissipation member 200.

According to the present embodiment described above, the heat dissipation pattern 125 and the external output pattern 126 are thermally connected to the heat dissipation member 200 through the heat dissipation pad 75, the heat dissipation via 66, and the insulated heat dissipation substrate 20. Further, the heat dissipation pattern 125 and the external output pattern 126 are portions where a large quantity of current easily flows and easily generate heat. Therefore, the heat of the heat dissipation pattern 125 and the external output pattern 126 can be effectively dissipated to the heat dissipation member 200.

(1) In the present embodiment, the heat dissipation pattern 125 is electrically connected to the heat dissipation wiring layer 23 through the heat dissipation pad 75 and the heat dissipation via 66. Therefore, the current flowing through the heat dissipation pattern 125 also flows through the heat dissipation pad 75, the heat dissipation via 66, and the heat dissipation wiring layer 23. Accordingly, the density of the current flowing through the heat dissipation pattern 125 can be reduced, and the generation of heat by the heat dissipation pattern 125 itself can be suppressed.

### Second Embodiment

A second embodiment will be hereinafter described. The present embodiment is different from the first embodiment in that a high thermal conductive member is disposed on the second surface 20b of the insulating heat dissipation substrate 20. The other configurations of the present embodiment are similar to those of the first embodiment, and therefore a description of the similar configurations will not be repeated.

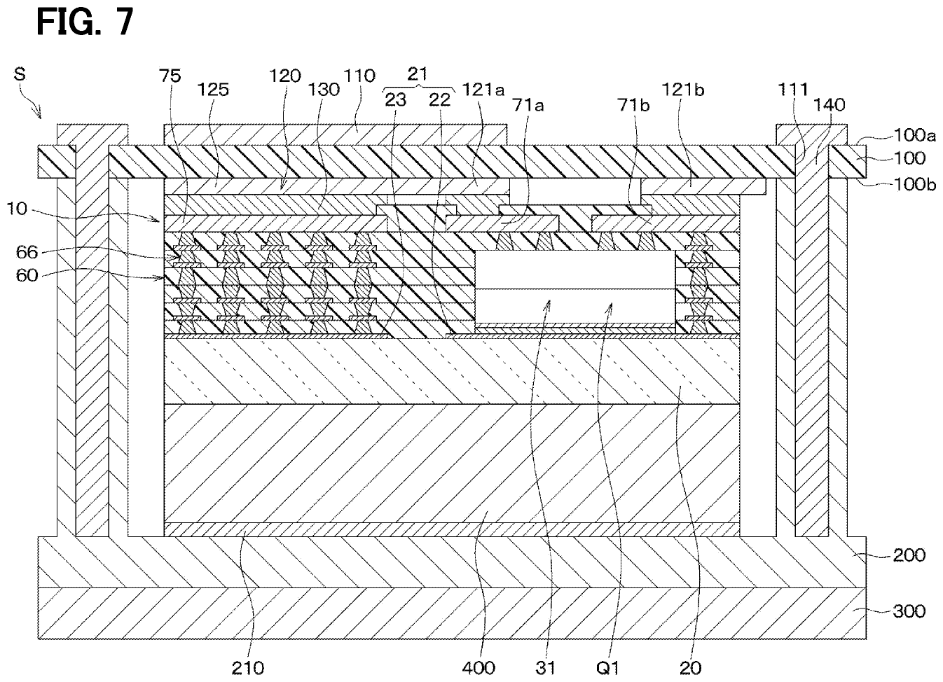

In the semiconductor package 10 of the present embodiment, as shown in FIG. 7, a high thermal conductive member 400 having a higher thermal conductivity than the insulating heat dissipation substrate 20 is arranged on the second surface 20b of the insulating heat dissipation substrate 20. The insulating heat dissipation substrate 20 is bonded to the insulating heat dissipation member 200 through the high thermal conductive member 400. That is, the high thermal conductive member 400 is arranged between the insulating heat dissipation substrate 20 and the heat dissipation member 200.

Note that the high thermal conductive member 400 is made of, for example, copper. The insulating heat dissipation substrate 20 and the high thermal conductive member 400 are bonded to each other by, for example, a direct bonding of copper (DBC) method, an active metal brazing (AMB) method, an aluminum molten metal bonding method, or the like.

Furthermore, the high thermal conductive member 400 of the present embodiment is thicker than the insulating heat dissipation substrate 20.

According to the present embodiment described above, the heat dissipation pattern 125 and the external output pattern 126 are thermally connected to the heat dissipation member 200 through the heat dissipation pad 75, the heat dissipation via 66, and the insulated heat dissipation substrate 20. Therefore, the similar effects to those of the first embodiment can be achieved.

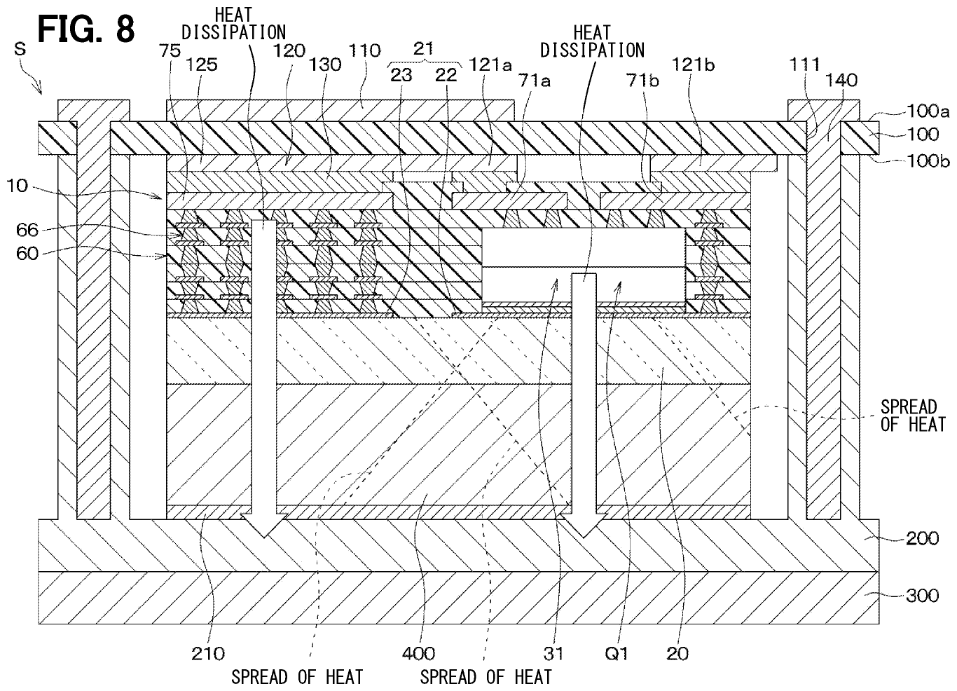

(1) In the present embodiment, since the high thermal conductive member 400 is provided, heat dissipation performance can be improved. That is, in a case where the high thermal conductive member 400 is not provided and the insulated heat dissipation substrate 20 is thin, the heat transferred from the semiconductor package 10 and the heat dissipation pad 75 is not sufficiently spread on the second surface 20b of the insulated heat dissipation substrate 20. As a result, the temperature may be locally increased or decreased. In such a case, since the temperature of the second surface 20b of the insulating heat dissipation substrate 20 varies depending on the areas, the temperature of the bonding member 210 also tends to vary. As a result, there is a possibility that the heat dissipation performance to the heat dissipation member 200 through the bonding member 210 may decrease. On the other hand, in the present embodiment, the high thermal conductive member 400 is arranged on the second surface 20b of the insulating heat dissipation substrate 20. Therefore, as shown in FIG. 8, the heat transferred from the semiconductor package 10 and the heat dissipation pad 75 to the insulated heat dissipation substrate 20 is likely to spread in the planar direction by the high thermal conductive member 400. In other words, it is possible to suppress the temperature of the portion bonded to the bonding member 210 from partially increasing or decreasing. Therefore, since it is possible to suppress the temperature of the bonding member 210 from partially increasing or decreasing, the heat can be easily transferred to the heat dissipation member 200 through substantially the entire bonding member 210. Accordingly, it is possible to improve the heat dissipation performance.

(2) In the present embodiment, the high thermal conductive member 400 is thicker than the insulating heat dissipation substrate 20. Therefore, on the side of the portion of the high thermal conductive member 400 bonded to the heat dissipation member 200, the overall temperature variation is further suppressed. Furthermore, it is possible to easily transfer heat to the heat dissipation member 200 through substantially the entire bonding member 210.

### Third Embodiment

A third embodiment will be hereinafter described. The present embodiment is different from the second embodiment in that the high thermal conductive member 400 is formed with a groove portion. The other configurations of the present embodiment are similar to those of the second embodiment, and therefore a description of the similar configurations will not be repeated.

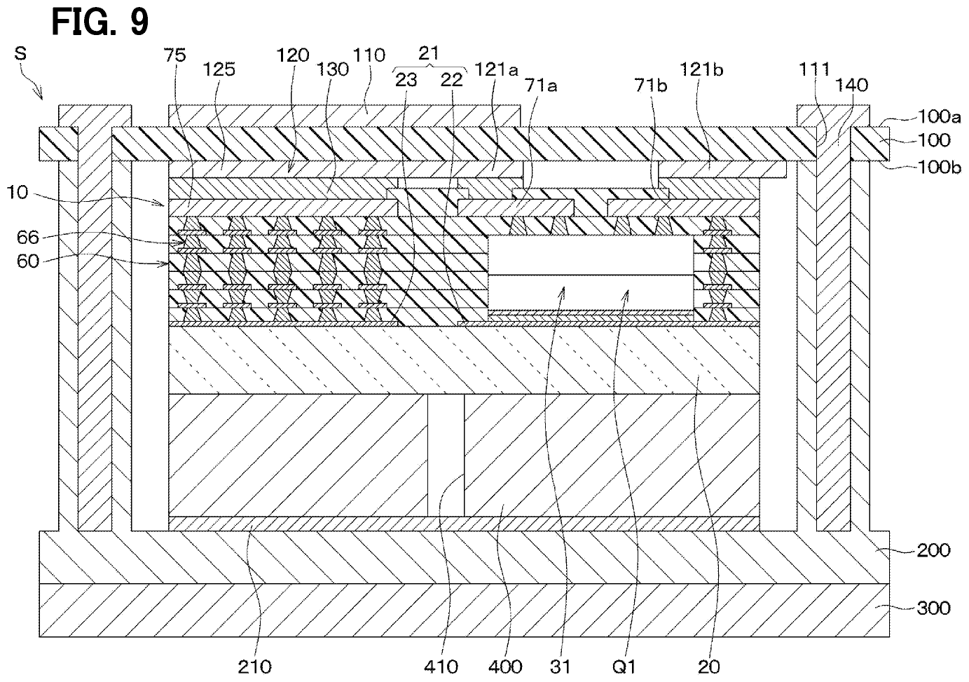

In the semiconductor device S of the present embodiment, as shown in FIG. 9, the high thermal conductive member 400 is formed with a groove portion 410. Specifically, the groove portion 410 is formed between the heat dissipation pad 75 (i.e., the heat dissipation pattern 125) and the first semiconductor chip 31 in the normal direction. In a cross section different from that shown in FIG. 9, the groove portion 410 is formed between the heat dissipation pad 75 and the second to fourth semiconductor chips 32 to 34 in the normal direction. Further, in the present embodiment, the groove portion 410 is formed so as to extend from the heat dissipation member 200 side and to reach the insulating heat dissipation substrate 20. The groove portion 410 is filled with air or the like, and has a lower thermal conductivity than the high thermal conductive member 400.

According to the present embodiment described above, the heat dissipation pattern 125 and the external output pattern 126 are thermally connected to the heat dissipation member 200 through the heat dissipation pad 75, the heat dissipation via 66, and the insulating heat dissipation substrate 20. Therefore, the similar effects to those in the first embodiment can be achieved.

(1) In the present embodiment, the groove portion 410 is formed in the high thermal conductive member 400 between the heat dissipation pad 75 and the first to fourth semiconductor chips 31 to 34 in the normal direction. Therefore, thermal interference can be suppressed. That is, for example, if the temperature of the heat dissipation pattern 125 becomes significantly higher than that of the first to fourth semiconductor chips 31 to 34 due to the usage environment, the heat transferred from the heat dissipation pattern 125 to the high thermal conductive member 400 may be transferred toward the first to fourth semiconductor chips 31 to 34. Therefore, by forming the groove portion 410 as in the present embodiment, thermal interference between the heat dissipation pattern 125 and the first to fourth semiconductor chips 31 to 34 can be suppressed, and heat can be efficiently dissipated to the heat dissipation member 200.

### Fourth Embodiment

A fourth embodiment will be hereinafter described. The present embodiment is different from the third embodiment in that an embedded member is added to the groove portion 410. The other configurations of the present embodiment are similar to those of the third embodiment, and therefore a description of the similar configurations will not be repeated.

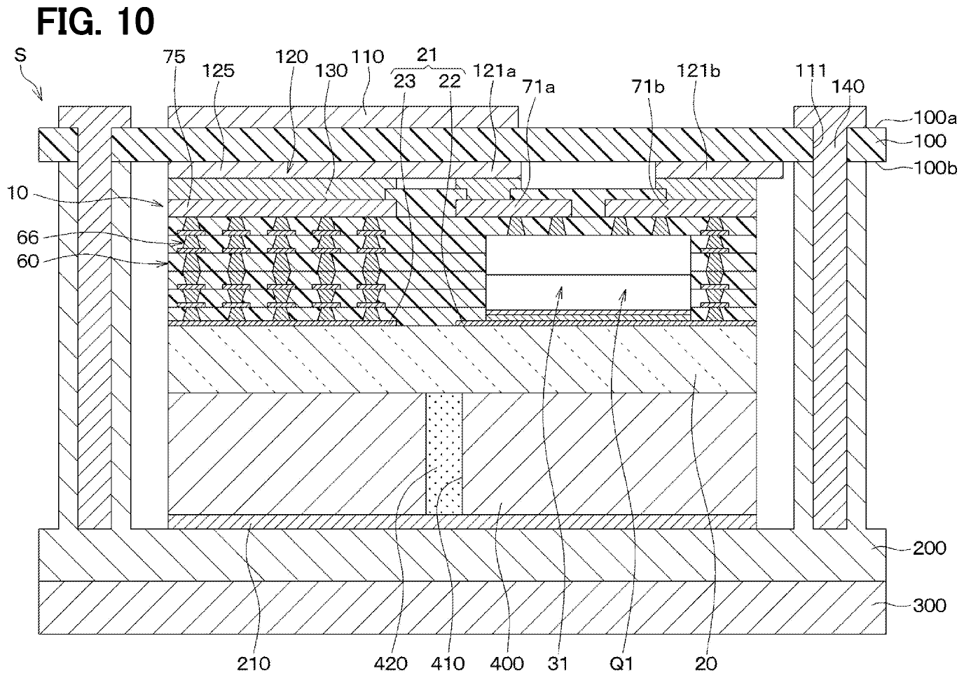

In the semiconductor package 10 of the present embodiment, as shown in FIG. 10, an embedded member 420 is placed in the groove portion 410. The embedded member 420 is made of a material having a lower thermal conductivity than the high thermal conductive member 400, and is made of, for example, a silicon oxide film.

According to the present embodiment described above, the heat dissipation pattern 125 and the external output pattern 126 are thermally connected to the heat dissipation member 200 through the heat dissipation pad 75, the heat dissipation via 66, and the insulating heat dissipation substrate 20. Therefore, the similar effects to those of the first embodiment can be achieved.

(1) In the present embodiment, the embedded member 420 is placed in the groove portion 410. For this reason, it is possible to suppress, for example, foreign matter having a higher thermal conductivity than the high thermal conductive member 400 from entering the groove portion 410. Accordingly, it is possible to suppress the effect of the groove portion 410 from decreasing.

### Fifth Embodiment

A fifth embodiment will be hereinafter described. In the present embodiment, the configuration of the heat dissipation connection member is changed from that of the first embodiment. The other configurations of the present embodiment are similar to those of the first embodiment, and therefore a description of the similar configurations will not be repeated.

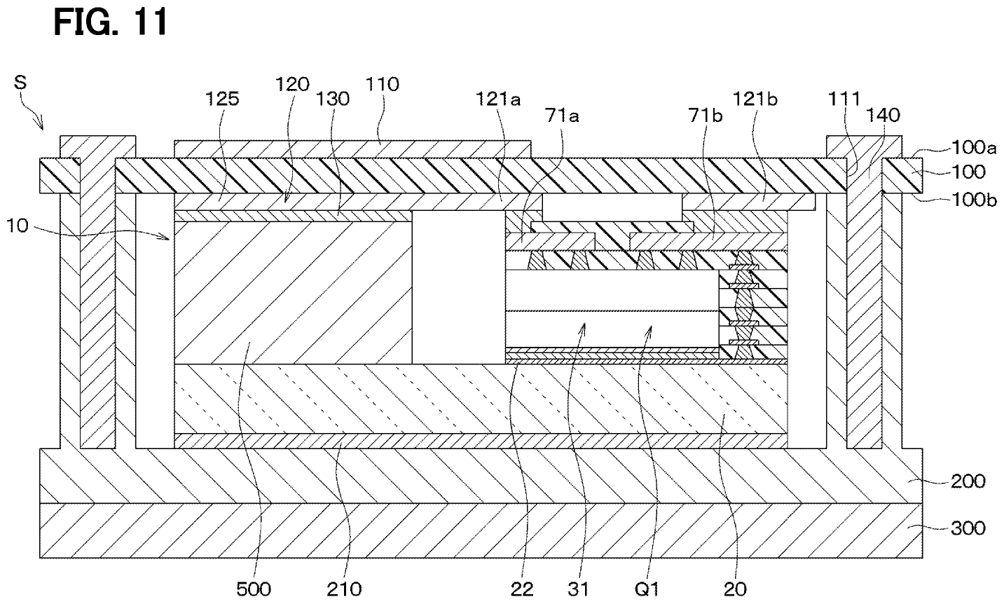

In the semiconductor device S of the present embodiment, as shown in FIG. 11, the semiconductor package 10 is not provided with the heat dissipation pad 75, and the insulating heat dissipation substrate 20 is not provided with the heat dissipation wiring layer 23. Further, the sealing member 60 is arranged so that a portion of the first surface 20a of the insulating heat dissipation substrate 20 facing the heat dissipation pattern 125 is exposed. The heat dissipation pattern 125 of the wiring board 100 and the insulating heat dissipation substrate 20 are thermally connected through a block body 500 made of copper or the like having high thermal conductivity. In the present embodiment, the block body 500 corresponds to the heat dissipation connection member.

Even if the heat dissipation pattern 125 of the wiring board 100 and the insulating heat dissipation substrate 20 are thermally connected by the block body 500 as in the present embodiment described above, the similar effects to those in the first embodiment can be achieved.

(1) In the present embodiment, the heat dissipation pattern 125 of the wiring board 100 and the heat dissipation wiring layer 23 of the insulating heat dissipation substrate 20 are thermally connected by the block body 500. Therefore, the configuration of the semiconductor package 10 can be simplified.

### OTHER EMBODIMENTS

Although the present disclosure has been described in accordance with the embodiments, it is understood that the present disclosure is not limited to such embodiments or structures. The present disclosure encompasses various modifications and variations within the scope of equivalents. In addition, various combinations and configurations, as well as other combinations and configurations that include only one element, more, or less, fall within the scope and spirit of the present disclosure.

For example, in each of the embodiments described above, the number of semiconductor chips included in the semiconductor package 10 can be changed as appropriate.

In each of the embodiments described above, the configuration of each of the semiconductor chips 31 to 34 can be changed as appropriate. For example, each of the semiconductor chips 31 to 34 may be made using a silicon substrate, a silicon carbide substrate, or the like. Furthermore, the semiconductor element formed in each of the semiconductor chips 31 to 34 can be changed as appropriate. For example, a vertical element that allows current to flow in the thickness direction may be formed.

Furthermore, in each of the embodiments described above, the sealing member 60 may be formed by, for example, injection molding, instead of the plate members 61 being stacked and integrated.

Further, in each of the embodiments described above, the heat dissipation pad 75 may be divided into a plurality of pad portions. For example, the heat dissipation pad 75 may have portions located adjacent to the first to fourth drain pads 71a to 74a in the first direction, and these portions may be separated from each other.

In the first to fourth embodiments, the heat dissipation pattern 125 and the heat dissipation wiring layer 23 may not be electrically connected to each other as long as the heat dissipation pattern 125 and the heat dissipation wiring layer 23 are thermally connected.

In the first to fourth embodiments described above, the heat dissipation via 66 may have a polygonal cylindrical shape. Also, only one heat dissipation via 66 may be provided.

In the first to fourth embodiments described above, as long as the heat dissipation pattern 125 is thermally connected to the insulating heat dissipation substrate 20, the heat dissipation wiring layer 23 may not be formed.

In the second to fourth embodiments described above, the high thermal conductive member 400 may be thinner than the insulating heat dissipation substrate 20.

In the third and fourth embodiments described above, the groove portion 410 may be formed from the high thermal conductive member 400 to the insulating heat dissipation substrate 20, or may be formed only in the insulating heat dissipation substrate 20. That is, the groove portion 410 only needs to be formed in at least one of the insulating heat dissipation substrate 20 and the high thermal conductive member 400.

The embodiments described above can be appropriately combined. For example, the second to fourth embodiments may be combined with the fifth embodiment to include the high thermal conductive member 400.

What is claimed is:

1. A semiconductor device comprising:
a wiring board having a first surface and a second surface opposite to the first surface, and including a wiring pattern disposed on the second surface;
a semiconductor package including a semiconductor chip formed with a semiconductor element, an insulating heat dissipation substrate having a first surface on which the semiconductor chip is arranged and a second surface, and an element pad being electrically connected to the semiconductor chip, the semiconductor package being mounted on the wiring board so that the element pad is connected to the wiring pattern; and
a heat dissipation member disposed opposite to the wiring board with respect to the semiconductor package, the heat dissipation member facing the second surface of the insulating heat dissipation substrate and being thermally connected to the insulating heat dissipation substrate, wherein
the wiring pattern includes a heat dissipation pattern that is connected to the semiconductor element and allows a current to flow according to an operation of the semiconductor element, and
the semiconductor device further comprising:
a heat dissipation connection member disposed between the heat dissipation pattern and the insulating heat dissipation substrate to thermally connect the heat dissipation pattern and the insulating heat dissipation substrate.

2. The semiconductor device according to claim 1, wherein
the semiconductor package includes a heat dissipation pad connected to the heat dissipation pattern, and a heat dissipation via as the heat dissipation connection member connecting the insulating heat dissipation substrate and the heat dissipation pad, and
the heat dissipation pattern is thermally connected to the insulating heat dissipation substrate through the heat dissipation pad and the heat dissipation via.

3. The semiconductor device according to claim 2, wherein
the insulating heat dissipation substrate has a heat dissipation wiring layer on the first surface thereof and at a position different from a position where the semiconductor chip is arranged, and
the heat dissipation pattern is electrically connected to the heat dissipation wiring layer through the heat dissipation pad and the heat dissipation via.

4. The semiconductor device according to claim 1, wherein
the heat dissipation connection member includes a block body that is a separate member from the semiconductor package, and
the heat dissipation pattern is thermally connected to the insulating heat dissipation substrate through the block body.

5. The semiconductor device according to claim 1, further comprising:
a high thermal conductive member disposed between the insulating heat dissipation substrate and the heat dissipation member, the high thermal conductive member being made of a material having a thermal conductivity higher than that of the insulating heat dissipation substrate.

6. The semiconductor device according to claim 5, wherein
the high thermal conductive member is thicker than the insulating heat dissipation substrate.

7. The semiconductor device according to claim 5, wherein
at least one of the insulating heat dissipation substrate or the high thermal conductive member is formed with a groove portion at a position between the heat dissipation pattern and the semiconductor chip in a normal direction to the insulating heat dissipation substrate.

8. The semiconductor device according to claim 7, further comprising:
an embedded member disposed in the groove portion, the embedded member being made of a material having a thermal conductivity lower than that of the high thermal conductive member.

9. The semiconductor device according to claim 1, wherein
the insulating heat dissipation substrate is formed with a chip wiring layer,
the semiconductor chip includes a semiconductor substrate containing gallium nitride,
the semiconductor chip has, as the semiconductor element, a horizontal element that has a drain electrode, a source electrode and a gate electrode, and allows a current to flow along a planar direction of the semiconductor substrate,
the semiconductor chip has a rear surface electrode electrically connected to the chip wiring layer on a surface facing the insulating heat dissipation substrate, and
the source electrode is connected to the rear surface electrode through the chip wiring layer.

10. The semiconductor device according to claim 1, wherein
the semiconductor package has a multilayer sealing member sealing the semiconductor chip,
the multilayer sealing member includes a plurality of film members integrated to each other, and
the element pad and the semiconductor chip are electrically connected to each other through a through-via formed in the plurality of film members.
